(19) United States
(12) Patent Application Publication
(10) Pub. No.: US 2016/0154733 A1
(43) Pub. Date: Jun. 2, 2016

(54) METHOD OF OPERATING SOLID STATE DRIVE

(71) Applicant: SAMSUNG ELECTRONICS CO., LTD., SUWON-SI (KR)

(72) Inventors: SUN-YOUNG LIM, HWASEONG-SI (KR); CHUL-UNG KIM, SEOUL (KR); JONG-HYUN CHOI, SUWON-SI (KR)

(21) Appl. No.: 14/956,065

(22) Filed: Dec. 1, 2015

(30) Foreign Application Priority Data
Dec. 1, 2014 (KR) 10-2014-0169453

(51) Int. Cl. G06F 12/02; G11C 29/52; G06F 11/10; G06F 12/14; G06F 12/06

(52) U.S. Cl. CPC G06F 12/0246; G06F 12/1425; G06F 12/0638; G06F 11/1072; G06F 11/1016; G11C 29/52; G06F 2212/1052; G06F 2212/7201; G06F 2212/205

(57) ABSTRACT

In a method of operating a solid state drive including a non-volatile memory, a volatile memory and a controller, the controller reads fail information of the volatile memory from a fail information region included in the non-volatile memory. The controller maps a logical address of data to a physical address of the volatile memory based on a bad address list and a clean address list that are generated based on the fail information. The controller loads the data into the volatile memory according to the address mapping. The method of operating a solid state drive may block access to fail addresses corresponding to failed cells included in the solid state drive by sequentially mapping logical addresses to physical addresses of a volatile memory included in the solid state drive based on a clean address list and a bad address list that are generated based on a fail information.

### CROSS-REFERENCE TO RELATED APPLICATION

This application claims priority under 35 USC §119 to Korean Patent Applications No. 10-2014-0169453, filed on Dec. 1, 2014 in the Korean Intellectual Property Office (KIPO), the contents of which are herein incorporated by reference in their entirety.

### TECHNICAL FIELD

Example embodiments relate generally to a solid state drive and more particularly to a method of operating a solid state drive.

### BACKGROUND

A hard disk drive (HDD) is typically used as a data storage mechanism of an electronic device. Recently, however, a solid state drive (SSD) having flash memories is being used instead of an HDD as the data storage mechanism of electronic devices. If data is written in a bad cell corresponding to a failed address included in the solid state drive, or if the data is read from the bad cell, errors may be generated. Therefore, access to the failed address included in the solid state drive should be blocked.

### SUMMARY

Some example embodiments provide a method of operating a solid state drive capable of blocking access to failed addresses corresponding to failed cells included in the solid state drive by sequentially mapping logical addresses to physical addresses of a volatile memory included in the solid state drive based on a clean address list and a bad address list that are generated based on fail information.

In a method of operating a solid state drive including a non-volatile memory, a volatile memory and a controller, the controller reads fail information of the volatile memory from a fail information region included in the non-volatile memory. The controller maps a logical address of data to a physical address of the volatile memory based on a bad address list and a clean address list that are generated based on the fail information. The controller loads the data into the volatile memory according to the address mapping.

The clean address list that is generated based on the fail information may include normal addresses corresponding to normal cells (i.e. non-failed cells) of the volatile memory.

The clean address list may include a mapping table that sequentially maps the logical addresses of the data to the normal addresses.

The controller may sequentially map the logical addresses of the data to the normal addresses based on the clean address list.

The clean address list may be stored in the volatile memory.

The controller may include a plurality of central processor units. Each of the central processor units may sequentially map the logical addresses of the data to the normal addresses based on the clean address list.

The bad address list that is generated based on the fail information may include fail addresses corresponding to failed cells of the volatile memory.

The controller may stop mapping the logical addresses of the data to the fail addresses based on the bad address list.

The fail information may be stored in the fail information region based on a test result of the volatile memory. The test result may be determined by a test that is performed before the volatile memory is packaged.

The fail information stored in the fail information region may be updated based on a result of an error check and correction that is performed while the solid state drive operates.

The controller may update the clean address list and the bad address list based on the updated fail information.

The controller may sequentially map the logical addresses of the data to normal addresses corresponding to normal cells of the volatile memory based on the updated clean address list.

The controller may stop mapping the logical addresses of the data to fail addresses corresponding to failed cells of the volatile memory based on the updated bad address list.

In a method of operating a solid state drive including a non-volatile memory, a volatile memory and a controller, the controller stores fail information of the volatile memory in a fail information region included in the non-volatile memory. The controller reads the fail information from the fail information region. The controller maps a logical address of data to a physical address of the volatile memory based on a bad address list and a clean address list that are generated based on the fail information. The controller loads the data into the volatile memory according to the address mapping.

The controller may sequentially map the logical addresses of the data to normal addresses corresponding to normal cells of the volatile memory based on the clean address list.

The method of operating a solid state drive may block access to fail addresses corresponding to failed cells included in the solid state drive by sequentially mapping logical addresses to physical addresses of a volatile memory included in the solid state drive based on a clean address list and a bad address list that are generated based on a fail information.

### BRIEF DESCRIPTION OF THE DRAWINGS

Illustrative, non-limiting example embodiments will be more clearly understood from the following detailed description taken in conjunction with the accompanying drawings.

FIG. 1 is a flow chart illustrating a method of operating a solid state drive according to example embodiments.

FIG. 2 is a block diagram illustrating a solid state drive according to example embodiments.

FIG. 3 is a diagram for describing a clean address list and a bad address list that are generated based on fail information of a volatile memory included in the solid state drive of FIG. 2.

FIG. 4 is a diagram for describing an address mapping included in the method of operating the solid state drive of FIG. 1.

FIG. 5 is a diagram for describing a mapping table included in a clean address list.

FIG. 6 is a block diagram illustrating an example of a volatile memory included in the solid state drive of FIG. 2.

FIG. 7 is a block diagram illustrating an example of a non-volatile memory included in the solid state drive of FIG. 2.

FIG. 8 is a diagram illustrating an example of a memory cell array included in the non-volatile memory of FIG. 7.

FIG. 9 is a diagram illustrating another example of a memory cell array included in the non-volatile memory of FIG. 7.

FIG. 10 is a diagram illustrating still another example of a memory cell array included in the non-volatile memory of FIG. 7.

FIG. 11 is a diagram illustrating an example of an address mapping that a controller included in the solid state drive of FIG. 2 performs.

FIG. 12 is a diagram illustrating an example of a position where a clean address list is stored.

FIG. 13 is a diagram illustrating an example of an address mapping that a central processor unit included in a controller of the solid state drive of FIG. 2 performs.

FIG. 14 is a diagram illustrating another example of an address mapping that a central processor unit included in a controller of the solid state drive of FIG. 2 performs.

FIG. 15 is a diagram illustrating an operation example of blocking access to fail addresses.

FIG. 16 is a block diagram for describing a method of operating a solid state drive according to an example embodiment.

FIG. 17 is a diagram for describing a clean address list and a bad address list that are updated based on updated fail information.

FIG. 18 is a diagram illustrating an example of an address mapping that a controller included in the solid state drive performs based on an updated clean address list.

FIG. 19 is a diagram illustrating an operation example of blocking access to fail addresses based on an updated bad address list.

FIG. 20 is a flow chart illustrating a method of operating a solid state drive according to an example embodiment.

FIG. 21 is a flow chart illustrating a method of operating a solid state drive according to example embodiments.

FIG. 22 is a block diagram illustrating a mobile device including the solid state drive according to example embodiments.

FIG. 23 is a block diagram illustrating a computing system including the solid state drive according to example embodiments.

### DETAILED DESCRIPTION OF THE EMBODIMENTS

Various example embodiments will be described more fully hereinafter with reference to the accompanying drawings, in which some example embodiments are shown. The present inventive concept may, however, be embodied in many different forms and should not be construed as limited to the example embodiments set forth herein. Rather, these example embodiments are provided so that this disclosure will be thorough and complete, and will fully convey the scope of the present inventive concept to those skilled in the art. In the drawings, the sizes and relative sizes of layers and regions may be exaggerated for clarity. Like numerals refer to like elements throughout.

It will be understood that, although the terms first, second, third etc. may be used herein to describe various elements, these elements should not be limited by these terms. These terms are used to distinguish one element from another. Thus, a first element discussed below could be termed a second element without departing from the teachings of the present inventive concept. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted in the blocks may occur out of the order noted in the flowcharts. For example, two blocks shown in succession may in fact be executed substantially concurrently or the blocks may sometimes be executed in the reverse order, depending upon the functionality/acts involved.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

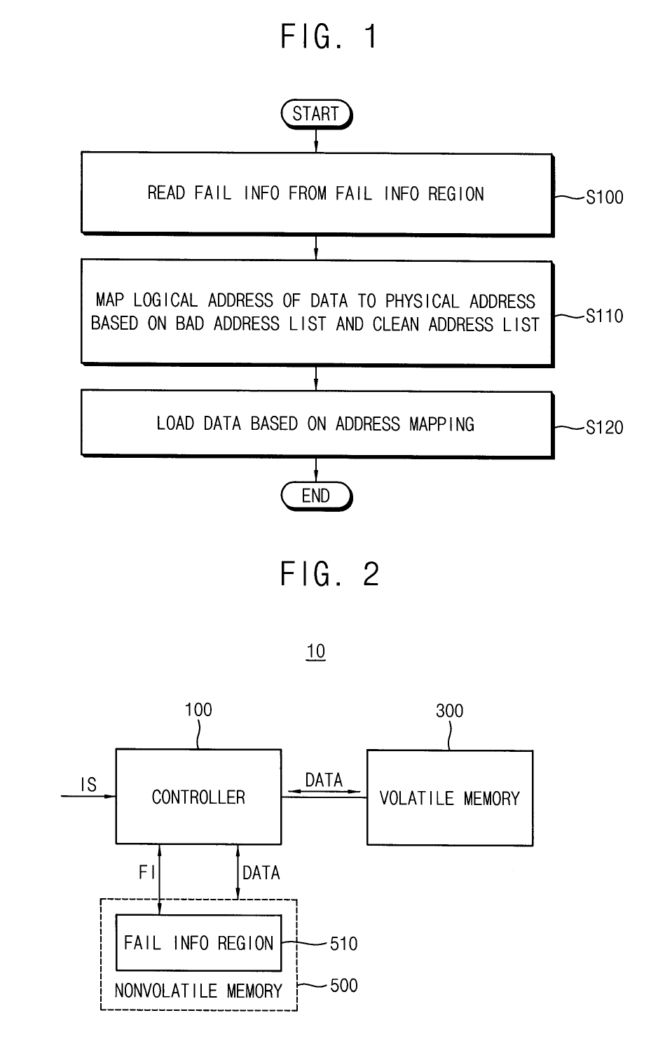

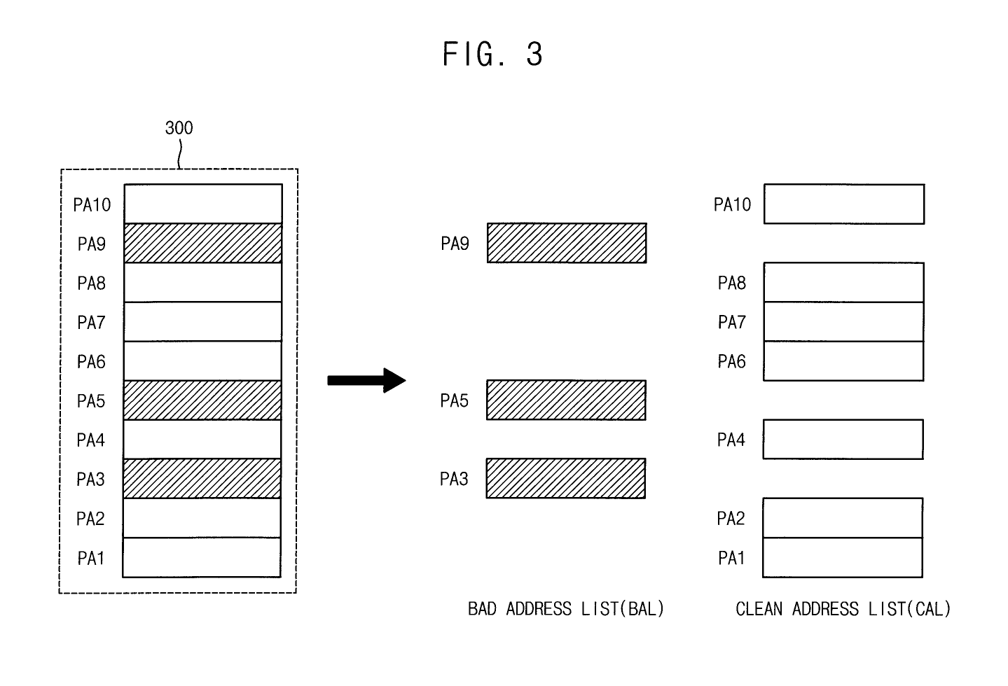

FIG. 1 is a flow chart illustrating a method of operating a solid state drive according to example embodiments and FIG. 2 is a block diagram illustrating a solid state drive according to example embodiments and FIG. 3 is a diagram for describing a clean address list and a bad address list that are generated based on a fail information of a volatile memory included in the solid state drive of FIG. 2.

Referring to FIGS. 1 to 3, a solid state drive 10 may include a non-volatile memory 500, a volatile memory 300 and a controller 100. If the power supply voltage is applied to the solid state drive 10, the controller 100, the non-volatile memory 500 and the volatile memory 300 included in the solid state drive 10 may be initialized based on a boot code. For example, the non-volatile memory 500 may be a flash memory. The volatile memory 300 may be a DRAM.

In a method of operating a solid state drive including a non-volatile memory 500, a volatile memory 300 and a controller 100, the controller 100 reads fail information FI of the volatile memory 300 from a fail information region 510 included in the non-volatile memory 500 (S100). For example, the fail information FI may be information of fail cells included in the volatile memory 300 of the solid state drive 10. The fail information FI may be stored in the fail information region 510. The fail information region 510 may be included in the non-volatile memory 500 of the solid state drive 10. After the controller 100, the non-volatile memory 500 and the volatile memory 300 included in the solid state drive 10 are initialized based on the boot code, the controller 100 may read the fail information FI of the volatile memory 300 from the fail information region 510 included in the non-volatile memory 500.

The controller 100 maps a logical address LA of data DATA to a physical address PA of the volatile memory 300 based on a bad address list BAL and a clean address list CAL that are generated based on the fail information FI (S110). For example, the addresses included in the volatile memory 300 of the solid state drive 10 may include first to tenth physical addresses PA1 to PA10. The fail addresses corresponding to the failed cells among the first to tenth physical addresses PA1 to PA10 included in the volatile memory 300 of the solid state drive 10 may be the third physical address PA3, the fifth physical address PA5 and the ninth physical address PA9. In this case, the fail information FI may be the information about the third physical address PA3, the fifth physical address PA5 and the ninth physical address PA9. The bad address list BAL that is generated based on the fail information FI may include the third physical address PA3, the fifth physical address PA5 and the ninth physical address PA9. The clean address list CAL that is generated based on the fail information FI may include the first physical address PA1, the second physical address PA2, the fourth physical address PA4, the sixth physical address PA6, the seventh physical address PA7, the eighth physical address PA8 and the tenth physical address PA10. The controller 100 may map the logical addresses LA of the data DATA to the physical addresses PA of the volatile memory 300 based on the bad address list BAL and the clean address list CAL.

The controller 100 loads the data DATA into the volatile memory 300 according to the address mapping (S120). The controller 100 may map the logical addresses LA of the data DATA to the physical address PA of the volatile memory 300 based on the clean address list CAL. For example, the controller 100 may sequentially map the logical addresses LA of the data DATA to the first physical address PA1, the second physical address PA2, the fourth physical address PA4, the sixth physical address PA6, the seventh physical address PA7, the eighth physical address PA8 and the tenth physical address PA10 corresponding to the clean address list CAL. The controller 100 may load the data DATA into the volatile memory 300. The data DATA may be included in the input signal IS. In addition, the data DATA may be provided from the non-volatile memory 500.

The method of operating a solid state drive may block access to fail addresses corresponding to failed cells included in the solid state drive 10 by sequentially mapping logical addresses LA to physical addresses PA of a volatile memory 300 included in the solid state drive 10 based on a clean address list CAL and a bad address list BAL that are generated based on a fail information FI.

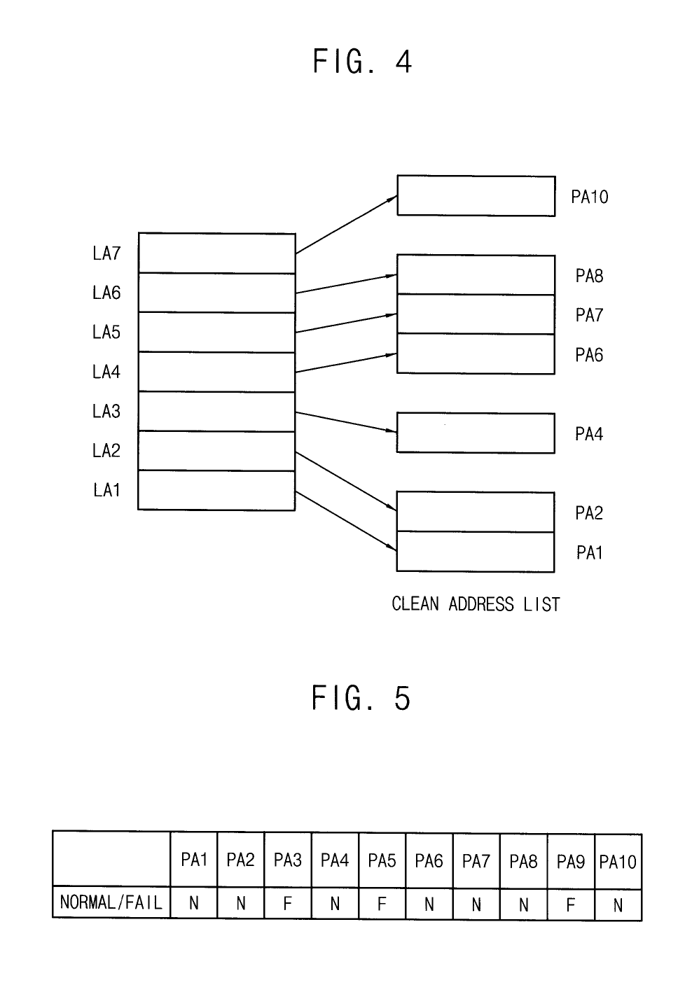

FIG. 4 is a diagram for describing an address mapping included in the method of operating the solid state drive of FIG. 1 and FIG. 5 is a diagram for describing a mapping table included in a clean address list.

Referring to FIGS. 4 and 5, the clean address list CAL that is generated based on the fail information FI may include normal addresses corresponding to normal cells of the volatile memory 300. For example, the fail addresses corresponding to the failed cells among the first to tenth physical addresses PA1 to PA10 included in the volatile memory 300 of the solid state drive 10 may be the third physical address PA3, the fifth physical address PA5 and the ninth physical address PA9. In this case, the bad address list BAL that is generated based on the fail information FI may include the third physical address PA3, the fifth physical address PA5 and the ninth physical address PA9. The clean address list CAL that is generated based on the fail information FI may include the first physical address PA1, the second physical address PA2, the fourth physical address PA4, the sixth physical address PA6, the seventh physical address PA7, the eighth physical address PA8 and the tenth physical address PA10. In this case, the memory cells corresponding to the physical addresses PA included in the clean address list CAL may be normal cells. The memory cells corresponding to the physical addresses PA included in the bad address list BAL may be fail cells.

In an example embodiment, the clean address list CAL may include a mapping table that sequentially maps the logical addresses LA of the data DATA to the normal addresses. The controller 100 may map the logical addresses LA of the data DATA to the physical addresses PA of the volatile memory 300 based on the clean address list CAL. For example, the controller 100 may map the logical address LA of the data DATA to the first physical address PA1 of the volatile memory 300. In addition, the controller 100 may map the logical address LA of the data DATA to the second physical address PA2 of the volatile memory 300. However, the controller 100 may stop mapping the logical address LA of the data DATA to the third physical address PA3 of the volatile memory 300. In the same manner, the controller 100 may stop mapping the logical address LA of the data DATA to the fifth physical address PA5 and ninth physical address PA9 of the volatile memory 300.

In an example embodiment, the controller 100 may sequentially map the logical addresses LA of the data DATA to the normal addresses based on the clean address list CAL. For example, the logical addresses LA of the data DATA may be a first to seventh logical addresses LA1 to LA7. The physical addresses PA of the volatile memory 300 included in the clean address list CAL may be the first physical address PA1, the second physical address PA2, the fourth physical address PA4, the sixth physical address PA6, the seventh physical address PA7, the eighth physical address PA8 and the tenth physical address PA10. The controller 100 may sequentially map the logical addresses LA of the data DATA to the normal addresses based on the clean address list CAL. For example, the controller 100 may map the first logical address LA1 of the data DATA to the first physical address PA1, map the second logical address LA2 of the data DATA to the second physical address PA2, map the third logical address LA3 of the data DATA to the fourth physical address PA4, map the fourth logical address LA4 of the data DATA to the sixth physical address PA6, map the fifth logical address LA5 of the data DATA to the seventh physical address PA7, map the sixth logical address LA6 of the data DATA to the eighth physical address PA8 and map the seventh logical address LA7 of the data DATA to the tenth physical address PA10.

The method of operating a solid state drive may block access to fail addresses corresponding to failed cells included in the solid state drive 10 by sequentially mapping logical addresses LA to physical addresses PA of a volatile memory 300 included in the solid state drive 10 based on a clean address list CAL and a bad address list BAL that are generated based on a fail information FI.

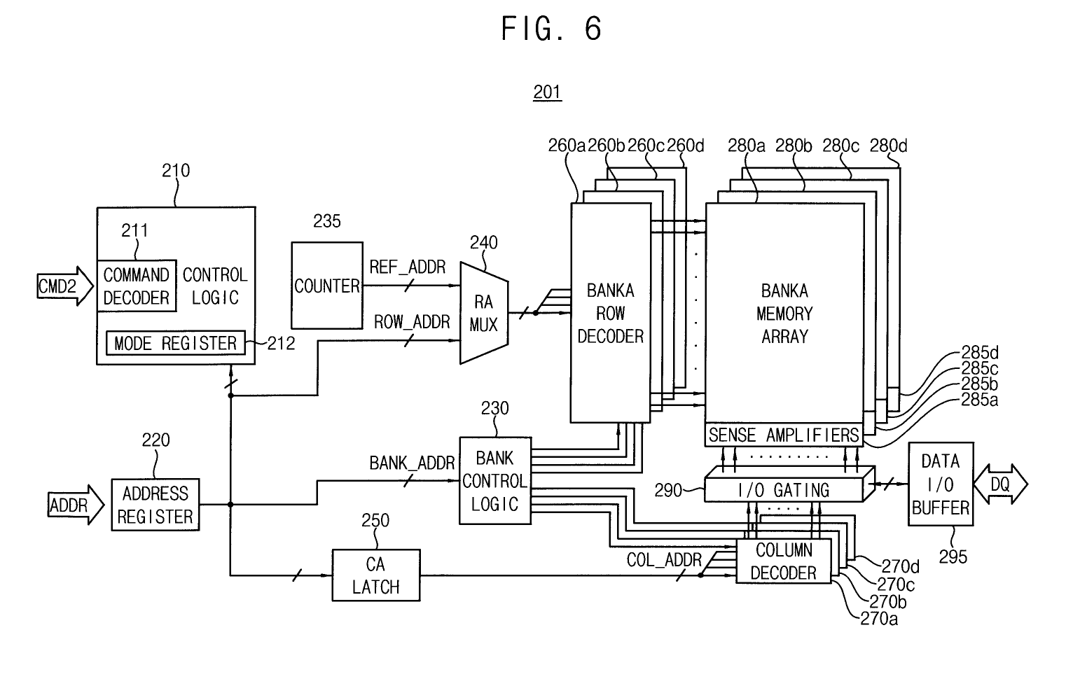

FIG. 6 is a block diagram illustrating an example of a volatile memory included in the solid state drive of FIG. 2. Referring to FIG. 6, the main memory 201 includes a control logic 210, an address register 220, a bank control logic 230, a row address multiplexer 240, a refresh counter 235, a fail address table 237, a column address latch 250, a row decoder 260, a column decoder 270, a memory cell array 280, a sense amplifier unit 285, an input/output gating circuit 290 and a data input/output buffer 295. In some embodiments, the memory device 201 may be a dynamic random access memory (DRAM), such as a double data rate synchronous dynamic random access memory (DDR SDRAM), a low power double data rate synchronous dynamic random access memory (LPDDR SDRAM), a graphics double data rate synchronous dynamic random access memory (GDDR SDRAM), a Rambus dynamic random access memory (RDRAM), etc.

The memory cell array 280 may include first through fourth bank arrays 280a, 280b, 280c and 280d. The row decoder 260 may include first through fourth bank row decoders 260a, 260b, 260c and 260d respectively coupled to the first through fourth bank arrays 280a, 280b, 280c and 280d, the column decoder 270 may include first through fourth bank column decoders 270a, 270b, 270c and 270d respectively coupled to the first through fourth bank arrays 280a, 280b, 280c and 280d, and the sense amplifier unit 285 may include first through fourth bank sense amplifiers 285a, 285b, 285c and 285d respectively coupled to the first through fourth bank arrays 280a, 280b, 280c and 280d. The first through fourth bank arrays 280a, 280b, 280c and 280d, the first through fourth bank row decoders 260a, 260b, 260c and 260d, the first through fourth bank column decoders 270a, 270b, 270c and 270d and the first through fourth bank sense amplifiers 285a, 285b, 285c and 285d may form first through fourth banks. The main memory 200 may include any number of banks.

The address register 220 may receive an address ADDR including a bank address BANK_ADDR, a row address ROW_ADDR and a column address COL_ADDR from a memory controller (not illustrated). The address register 220 may provide the received bank address BANK_ADDR to the bank control logic 230, may provide the received row address ROW_ADDR to the row address multiplexer 240, and may provide the received column address COL_ADDR to the column address latch 250.

The bank control logic 230 may generate bank control signals in response to the bank address BANK_ADDR. One of the first through fourth bank row decoders 260a, 260b, 260c and 260d corresponding to the bank address BANK_ADDR may be activated in response to the bank control signals, and one of the first through fourth bank column decoders 270a, 270b, 270c and 270d corresponding to the bank address BANK_ADDR may be activated in response to the bank control signals.

The row address multiplexer 240 may receive the row address ROW_ADDR from the address register 220, and may receive a refresh row address REF_ADDR from the refresh counter 235. The row address multiplexer 240 may selectively output the row address ROW_ADDR or the refresh row address REF_ADDR. A row address output from the row address multiplexer 240 may be applied to the first through fourth bank row decoders 260a, 260b, 260c and 260d.

The activated one of the first through fourth bank row decoders 260a, 260b, 260c and 260d may decode the row address output from the row address multiplexer 240, and may activate a word line corresponding to the row address. For example, the activated bank row decoder may apply a word line driving voltage to the word line corresponding to the row address.

The column address latch 250 may receive the column address COL_ADDR from the address register 220, and may temporarily store the received column address COL_ADDR. In some embodiments, in a burst mode, the column address latch 250 may generate column addresses that increment from the received column address COL_ADDR. The column address latch 250 may apply the temporarily stored or generated column address to the first through fourth bank column decoders 270a, 270b, 270c and 270d.

The activated one of the first through fourth bank column decoders 270a, 270b, 270c and 270d may decode the column address COL_ADDR output from the column address latch 250, and may control the input/output gating circuit 290 to output data corresponding to the column address COL_ADDR.

The input/output gating circuit 290 may include circuitry for gating input/output data. The input/output gating circuit 290 may further include an input data mask logic, read data latches for storing data output from the first through fourth bank arrays 280a, 280b, 280c and 280d, and write drivers for writing data to the first through fourth bank arrays 280a, 280b, 280c and 280d.

Data DQ to be read from one bank array of the first through fourth bank arrays 280a, 280b, 280c and 280d may be sensed by a sense amplifier coupled to the one bank array, and may be stored in the read data latches. The data DQ stored in the read data latches may be provided to the memory controller via the data input/output buffer 295. Data DQ to be written to one bank array of the first through fourth bank arrays 280a, 280b, 280c and 280d may be provide from the memory controller to the data input/output buffer 295. The data DQ provided to the data input/output buffer 295 may be written to the one array bank via the write drivers.

The control logic 210 may control operations of the memory device 201. For example, the control logic 210 may generate control signals for the memory device 201 to perform a write operation or a read operation. The control logic 210 may include a command decoder 211 that decodes a command CMD received from the memory controller and a mode register 212 that sets an operation mode of the memory device 201. For example, the command decoder 211 may generate the control signals corresponding to the command CMD by decoding a write enable signal (/WE), a row address strobe signal (/RAS), a column address strobe signal (/CAS), a chip select signal (/CS), etc. The command decoder 211 may further receive a clock signal (CLK) and a clock enable signal (/CKE) for operating the memory device 201 in a synchronous manner.

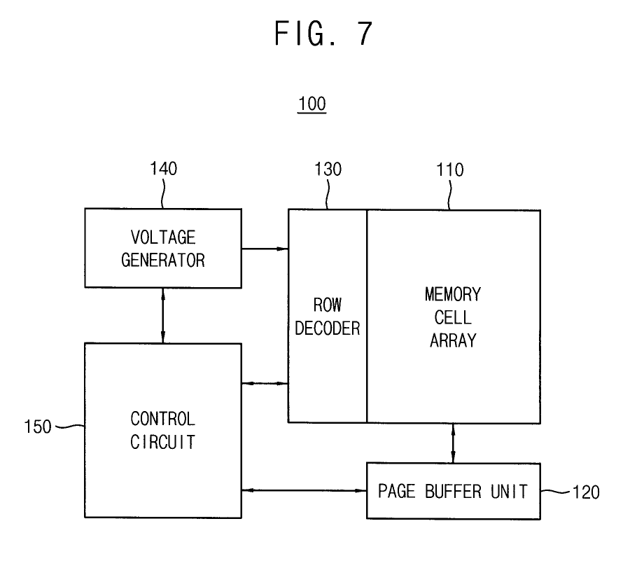

FIG. 7 is a block diagram illustrating an example of a non-volatile memory included in the solid state drive of FIG. 2.

Referring to FIG. 7, a nonvolatile memory device 100 may be a flash memory device. The nonvolatile memory device 100 comprises a memory cell array 110, a page buffer unit 120, a row decoder 130, a voltage generator 140, and a control circuit 150.

Memory cell array 110 comprises multiple memory cells connected to multiple word lines and multiple bit lines, respectively. The memory cells may be NAND or NOR flash memory cells and may be arranged in a two or three dimensional array structure.

In some embodiments, the memory cells may be single level cells (SLCs) or multi-level cells (MLCs). In embodiments including MLCs, a program scheme in a write mode may be, for instance, a shadow program scheme, a reprogrammable scheme, or an on-chip buffered program scheme.

Page buffer unit 120 is connected to the bit lines and stores write data programmed in memory cell array 110 or read data sensed from memory cell array 110. In other words, page buffer unit 120 may be operated as a write driver or a sensing amplifier according to an operation mode of flash memory device 100. For example, page buffer unit 120 may be operated as the write driver in the write mode and as the sensing amplifier in the read mode.

Row decoder 130 is connected to the word lines and selects at least one of the word lines in response to a row address. Voltage generator 140 generates word line voltages such as a program voltage, a pass voltage, a verification voltage, an erase voltage and a read voltage according to a control of control circuit 150. Control circuit 150 controls page buffer unit 120, row decoder 130 and voltage generator 140 to perform program, erase, and read operations on memory cell array 110.

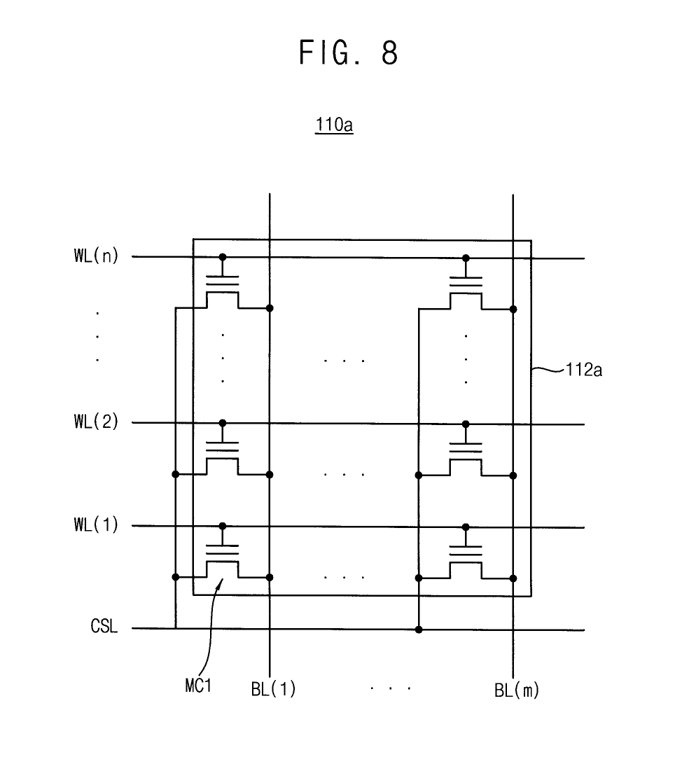

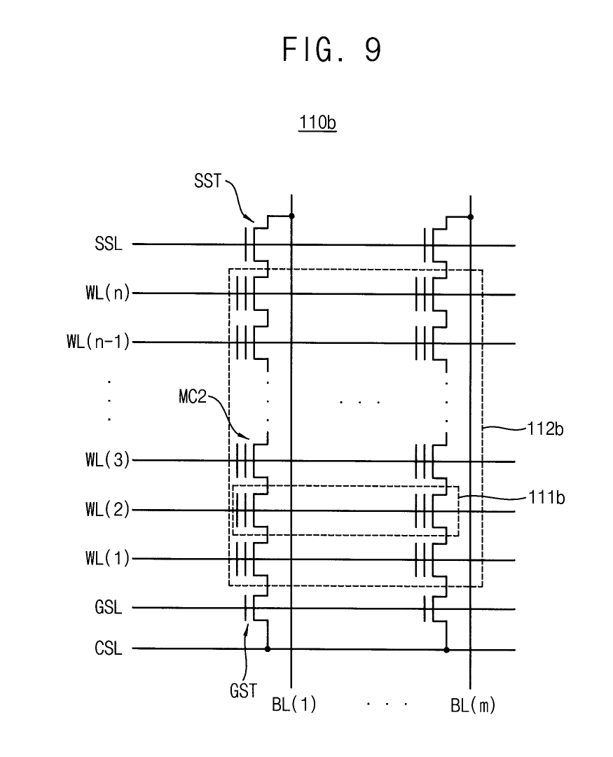

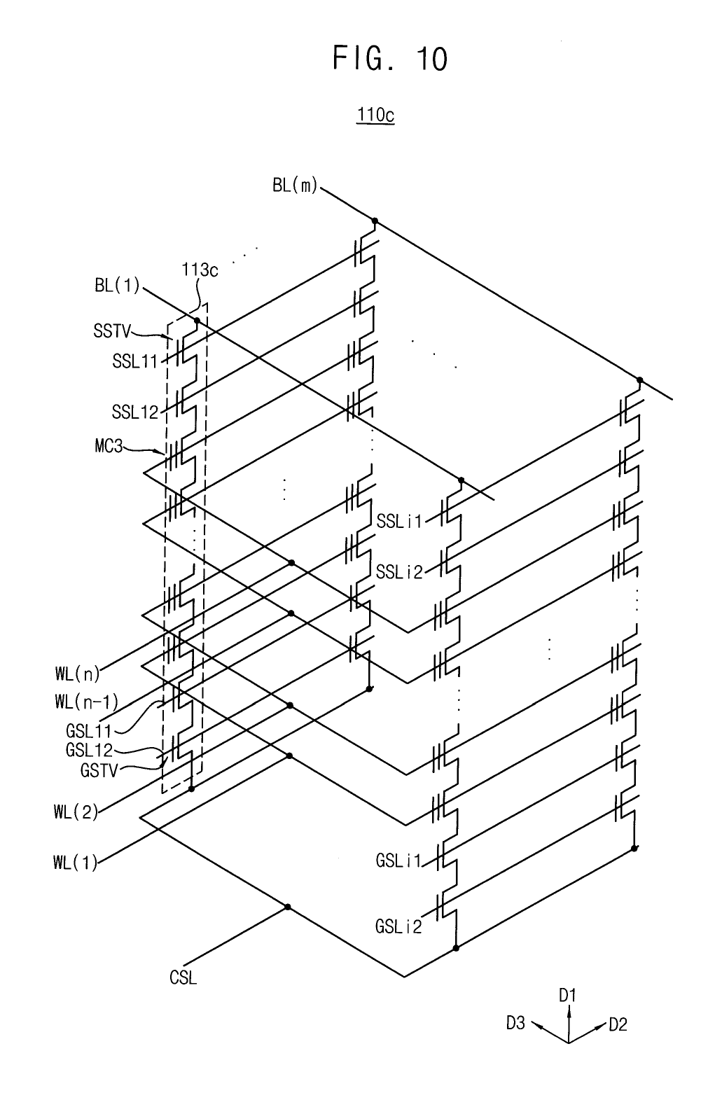

FIG. 8 is a diagram illustrating an example of a memory cell array included in the non-volatile memory of FIG. 7, FIG. 9 is a diagram illustrating another example of a memory cell array included in the non-volatile memory of FIG. 7 and FIG. 10 is a diagram illustrating still another example of a memory cell array included in the non-volatile memory of FIG. 7.

Referring to FIG. 8, memory cell array 110a may include multiple memory cells MC1. Memory cells MC1 located in the same row may be disposed in parallel between one of bit lines BL(1), . . . , BL(m) and a common source line CSL and may be connected in common to one of word lines WL(1), WL(2), . . . , WL(n)). For example, memory cells located in the first row may be disposed in parallel between the first bit line WL(1) and common source line CSL. The gate electrodes of the memory cells disposed in the first row may be connected in common to first word line WL(1). Memory cells MC1 may be controlled according to a level of a voltage applied to word lines WL(1), . . . , WL(n). The NOR flash memory device comprising memory cell array 110a may perform the write and read operations in units of byte or words and may perform the erase operation in units of block.

Referring to FIG. 9, memory cell array 110b comprises string selection transistors SST, ground selection transistors GST and memory cells MC2. String selection transistors SST are connected to bit lines BL(1), . . . , BL(m), and ground selection transistors GST are connected to common source line CSL. Memory cells MC2 disposed in the same row are disposed in series between one of bit lines BL(1), . . . , BL(m) and common source line CSL, and memory cells MCs disposed in the same column are connected in common to one of word lines WL(1), WL(2), WL(3), . . . , WL(n−1), WL(n). That is memory cells MC2 are connected in series between string selection transistors SST and ground selection transistors GST, and the word lines of 16, 32, or 64 are disposed between string selection line SSL and ground selection line GSL.

String selection transistors SST are connected to string selection line SSL such that string selection transistors SST may be controlled according to a level of the voltage applied from string selection line SSL thereto. Memory cells MC2 may be controlled according to a level of a voltage applied to word lines WL(1), . . . , WL(n).

The NAND flash memory device comprising memory cell array 110b performs write and read operations in units of page 111b, and it performs erase operations in units of block 112b. Meanwhile, according to some embodiments, each of the page buffers may be connected to even and odd bit lines one by one. In this case, the even bit lines form an even page, the odd bit lines form an odd page, and the even and odd pages may perform by turns and sequentially the write operation into memory cells MC2.

Referring to FIG. 10, memory cell array 110c comprises multiple strings 113c having a vertical structure. Strings 113c are formed in the second direction to form a string row. Multiple string rows are formed in the third row to form a string array. Each of strings 113c comprises ground selection transistors GSTV, memory cells MC3, and string selection transistors SSTV, which are disposed in series in the first direction between bit lines BL(1), . . . , BL(m) and common source line CSL.

Ground selection transistors GSTV are connected to ground selection lines GSL11, GSL12, . . . , GSLi1, GSLi2, respectively, and string selection transistors SSTV are connected to string selection lines SSL11, SSL12, . . . , SSLi1, SSLi2, respectively. Memory cells MC3 disposed in the same layer are connected in common to one of word lines WL(1), WL(2), . . . , WL(n−1), WL(n). Ground selection lines GSL11, . . . , GSLi2 and string selection lines SSL11, . . . , SSLi2 extend in the second direction and are formed along the third direction. Word lines WL(1), . . . , WL(n) extend in the second direction and are formed along the first and third directions. Bit lines BL(1), . . . , BL(m) extend in the third direction and are formed along the second direction. Memory cells MC3 are controlled according to a level of a voltage applied to word lines WL(1), . . . , WL(n).

Because the vertical flash memory device comprising memory cell array 110c comprises NAND flash memory cells, like the NAND flash memory device, the vertical flash memory device performs the write and read operations in units of pages and the erase operation in units of block.

In some embodiments, two string selection transistors in one string 113c are connected to one string selection line and two ground selection transistors in one string are connected to one ground selection line. Further, according to some embodiments, one string comprises one string selection transistor and one ground selection transistor.

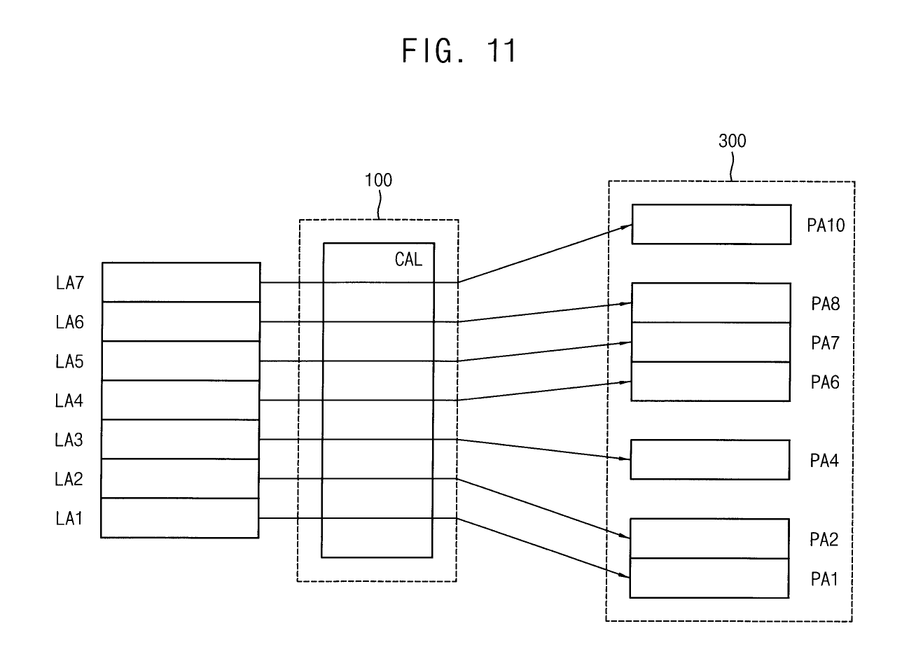

FIG. 11 is a diagram illustrating an example of an address mapping that a controller included in the solid state drive of FIG. 2 performs.

Referring to FIG. 11, the clean address list CAL may be placed in the controller 100. For example, the fail addresses corresponding to the failed cells among the first to tenth physical addresses PA1 to PA10 included in the volatile memory 300 of the solid state drive 10 may be the third physical address PA3, the fifth physical address PA5 and the ninth physical address PA9. In this case, the bad address list BAL that is generated based on the fail information FI may include the third physical address PA3, the fifth physical address PA5 and the ninth physical address PA9. The clean address list CAL that is generated based on the fail information FI may include the first physical address PA1, the second physical address PA2, the fourth physical address PA4, the sixth physical address PA6, the seventh physical address PA7, the eighth physical address PA8 and the tenth physical address PA10. In this case, the memory cells corresponding to the physical addresses PA included in the clean address list CAL may be normal cells. The memory cells corresponding to the physical addresses PA included in the bad address list BAL may be failed cells.

For example, the controller 100 may map the logical address LA of the data DATA to the first physical address PA1 of the volatile memory 300. In addition, the controller 100 may map the logical address LA of the data DATA to the second physical address PA2 of the volatile memory 300. However, the controller 100 may stop mapping the logical address LA of the data DATA to the third physical address PA3 of the volatile memory 300. In the same manner, the controller 100 may stop mapping the logical address LA of the data DATA to the fifth physical address PA5 and ninth physical address PA9 of the volatile memory 300.

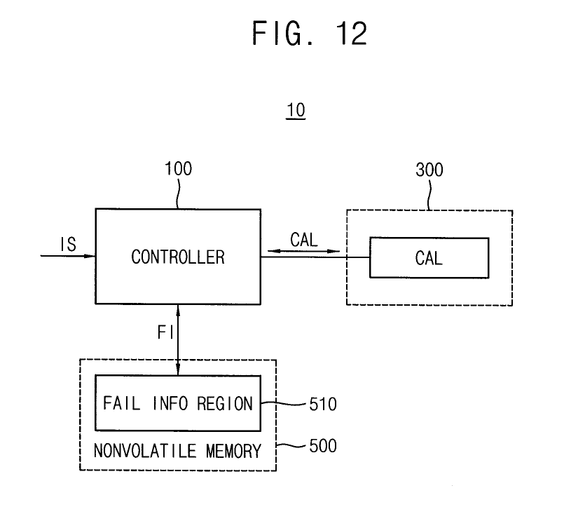

FIG. 12 is a diagram illustrating an example of a position where a clean address list is stored.

Referring to FIG. 12, a solid state drive 10 may include a non-volatile memory 500, a volatile memory 300 and a controller 100. In a method of operating a solid state drive including a non-volatile memory 500, a volatile memory 300 and a controller 100, the controller 100 reads the fail information FI of the volatile memory 300 from a fail information region 510 included in the non-volatile memory 500. The controller 100 maps a logical address LA of data DATA to a physical address of the volatile memory 300 based on a bad address list BAL and a clean address list CAL that are generated based on the fail information FI. The controller 100 loads the data DATA into the volatile memory 300 according to the address mapping.

In an example embodiment, the clean address list CAL may be stored in the volatile memory 300. For example, the controller 100 may generate the clean address list CAL and the bad address list BAL based on the fail information FI. The controller 100 may store the clean address list CAL in the volatile memory 300.

The method of operating a solid state drive may block access to fail addresses corresponding to failed cells included in the solid state drive 10 by sequentially mapping logical addresses LA to physical addresses PA of a volatile memory 300 included in the solid state drive 10 based on a clean address list CAL and a bad address list BAL that are generated based on a fail information FI.

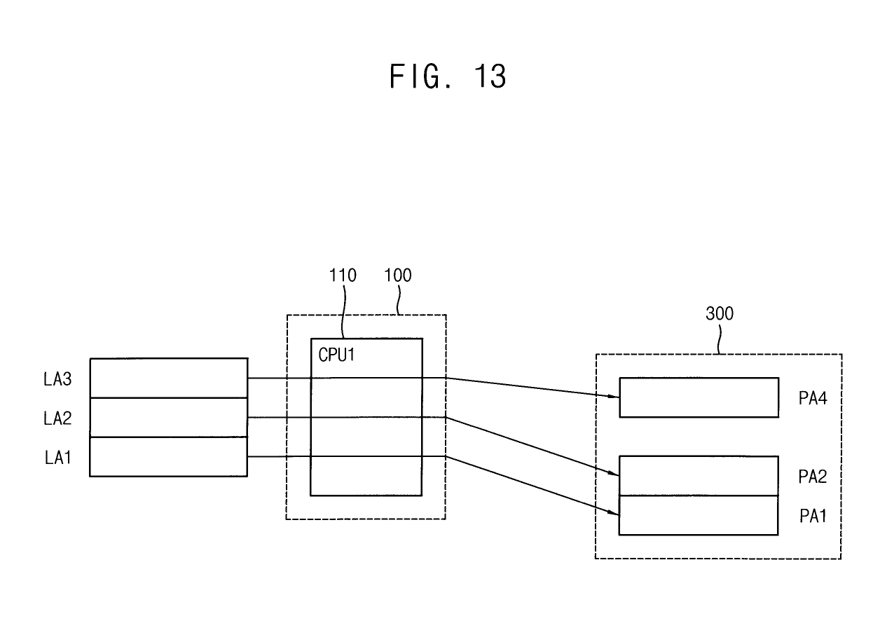

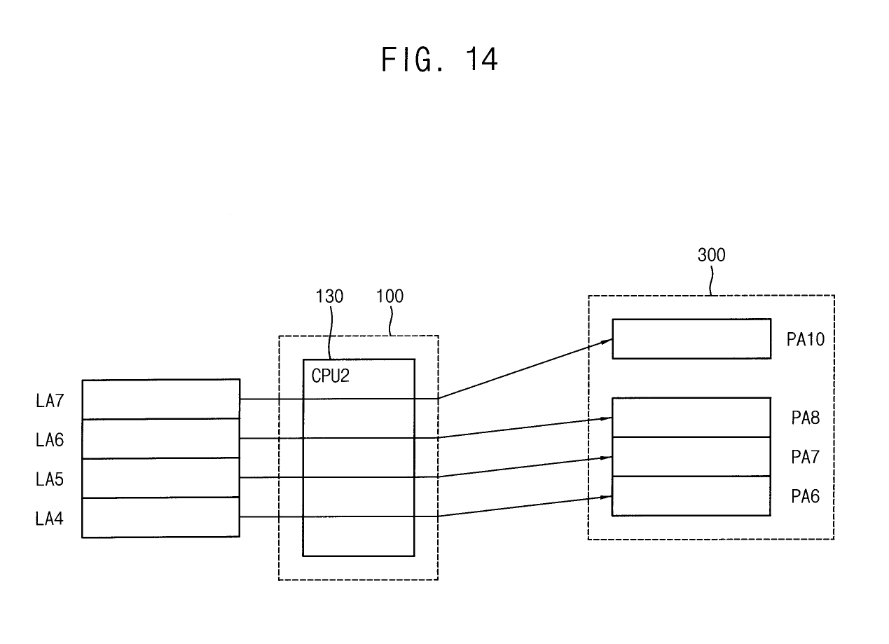

FIG. 13 is a diagram illustrating an example of an address mapping that a central processor unit included in a controller of the solid state drive of FIG. 2 performs and FIG. 14 is a diagram illustrating another example of an address mapping that a central processor unit included in a controller of the solid state drive of FIG. 2 performs.

Referring to FIGS. 13 and 14, the controller 100 may include a plurality of central processor units. Each of the central processor units may sequentially map the logical addresses LA of the data DATA to the normal addresses based on the clean address list CAL. For example, the plurality of central processor units may include a first central processor unit 110 and a second central processor unit 130. The first central processor unit 110 may map the first to third logical addresses LA1 to LA3 of the data DATA to the physical addresses PA of the volatile memory 300. The second central processor unit 130 may map the fourth to seventh logical addresses LA4 to LA7 of the data DATA to the physical addresses PA of the volatile memory 300. The fail addresses corresponding to the failed cells among the first to tenth physical addresses PA1 to PA10 included in the volatile memory 300 of the solid state drive 10 may be the third physical address PA3, the fifth physical address PA5 and the ninth physical address PA9. In this case, the bad address list BAL that is generated based on the fail information FI may include the third physical address PA3, the fifth physical address PA5 and the ninth physical address PA9. The clean address list CAL that is generated based on the fail information FI may include the first physical address PA1, the second physical address PA2, the fourth physical address PA4, the sixth physical address PA6, the seventh physical address PA7, the eighth physical address PA8 and the tenth physical address PA10.

For example, the first central processor unit 110 may sequentially map the logical addresses LA of the data DATA to the physical addresses PA included in the clean address list CAL. For example, the first central processor unit 110 may map the first logical address LA1 of the data DATA to the first physical address PA1, map the second logical address LA2 of the data DATA to the second physical address PA2 and map the third logical address LA3 of the data DATA to the fourth physical address PA4. For example, the second central processor unit 130 may sequentially map the logical addresses LA of the data DATA to the physical addresses PA included in the clean address list CAL. For example, the second central processor unit 130 may map the fourth logical address LA4 of the data DATA to the sixth physical address PA6, map the fifth logical address LA5 of the data DATA to the seventh physical address PA7, map the sixth logical address LA6 of the data DATA to the eighth physical address PA8 and map the seventh logical address LA7 of the data DATA to the tenth physical address PA10.

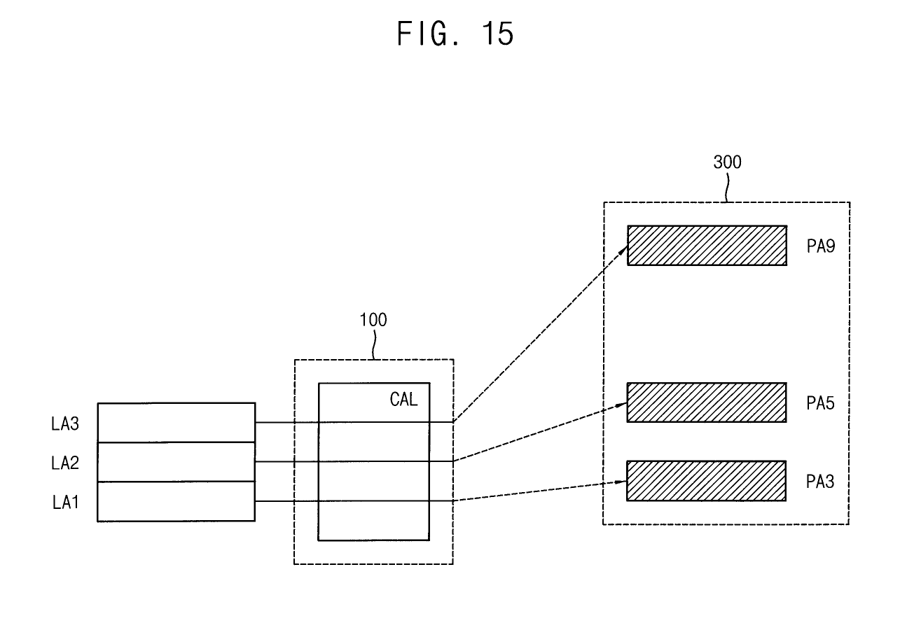

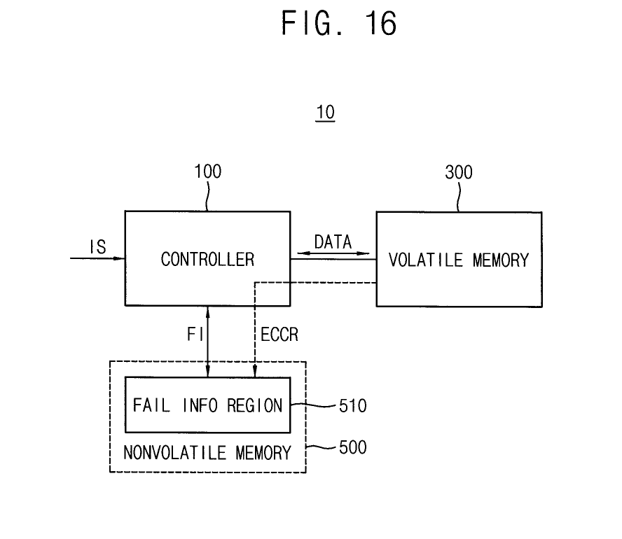

FIG. 15 is a diagram illustrating an operation example of blocking access to fail addresses.

Referring to FIG. 15, the bad address list BAL that is generated based on the fail information FI may include fail addresses corresponding to failed cells of the volatile memory 300. The bad address list BAL may be placed in the controller 100. For example, the fail addresses corresponding to the failed cells among the first to tenth physical addresses PA1 to PA10 included in the volatile memory 300 of the solid state drive 10 may be the third physical address PA3, the fifth physical address PA5 and the ninth physical address PA9. In this case, the bad address list BAL that is generated based on the fail information FI may include the third physical address PA3, the fifth physical address PA5 and the ninth physical address PA9.

In an example embodiment, the controller 100 may stop mapping the logical addresses LA of the data DATA to the fail addresses based on the bad address list BAL. For example, the logical addresses LA of the data DATA may be the first to third logical addresses LA1 to LA3. The controller 100 may stop mapping the first logical address LA1 of the data DATA to the third physical address PA3, the fifth physical address PA5 and the ninth physical address PA9. In addition, the controller 100 may stop mapping the second logical address LA2 of the data DATA to the third physical address PA3, the fifth physical address PA5 and the ninth physical address PA9. In addition, the controller 100 may stop mapping the third logical address LA3 of the data DATA to the third physical address PA3, the fifth physical address PA5 and the ninth physical address PA9.

In an example embodiment, the fail information FI may be stored in the fail information region 510 based on a test result of the volatile memory 300. The test result may be determined by a test that is performed before the volatile memory 300 is packaged.

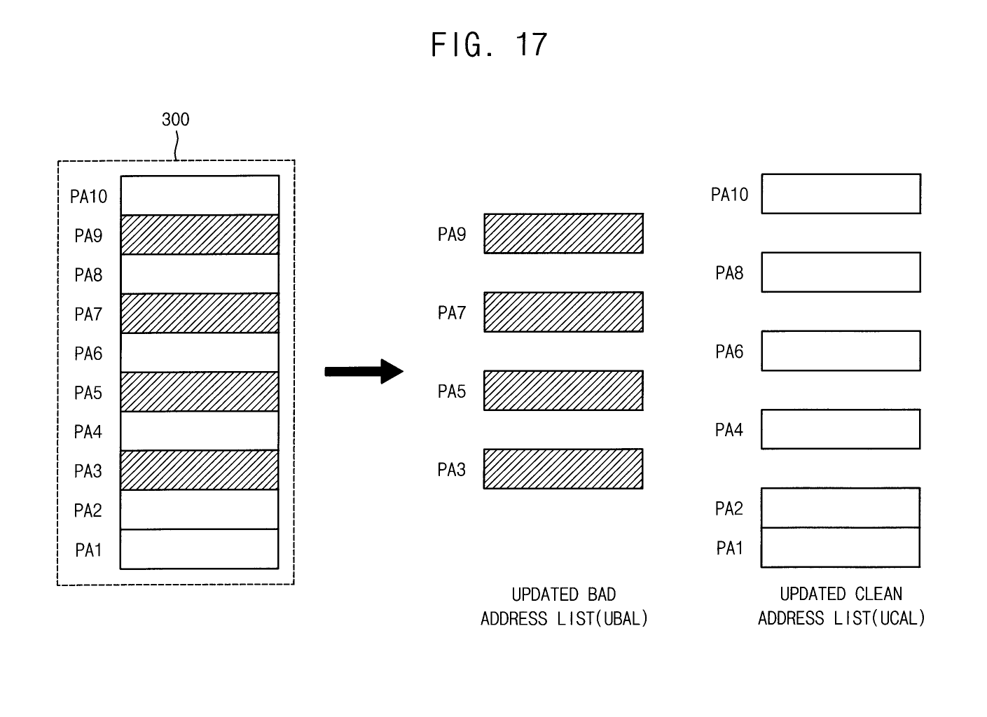

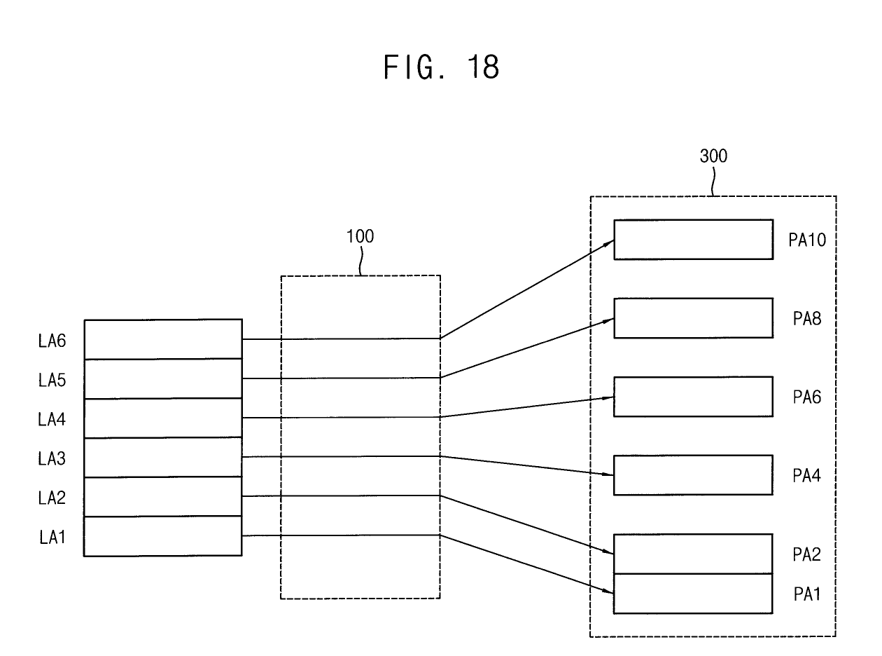

FIG. 16 is a block diagram for describing a method of operating a solid state drive according to an example embodiment, FIG. 17 is a diagram for describing a clean address list and a bad address list that are updated based on an updated fail information and FIG. 18 is a diagram illustrating an example of an address mapping that a controller included in the solid state drive performs based on an updated clean address list.

Referring to FIGS. 16 to 18, a solid state drive 10 may include a non-volatile memory 500, a volatile memory 300 and a controller 100. In a method of operating a solid state drive including a non-volatile memory 500, a volatile memory 300 and a controller 100, the controller 100 reads fail information FI of the volatile memory 300 from a fail information region 510 included in the non-volatile memory 500. The controller 100 maps a logical address LA of data DATA to a physical address of the volatile memory 300 based on a bad address list BAL and a clean address list CAL that are generated based on the fail information FI. The controller 100 loads the data DATA into the volatile memory 300 according to the address mapping.

In an example embodiment, the fail information FI stored in the fail information region 510 may be updated based on a result ECCR of an error check and correction that is performed while the solid state drive 10 operates. While the solid state drive 10 operates, the error check and correction may be performed for the data DATA that is stored in the volatile memory 300. In case the error is generated in the cells included in the volatile memory 300, the information of addresses corresponding to the error cells may be transferred to the controller 100. In case the information of addresses corresponding to the error cells is transferred to the controller 100, the controller 100 may update the fail information FI that is stored in the fail information region 510 included in the non-volatile memory 500 of the solid state drive 10. For example, while the error check and correction is performed for the data DATA stored in the volatile memory 300, the error may be generated in the cell corresponding to the seventh physical address PA7 of the volatile memory 300. In case the error is generated in the cell corresponding to the seventh physical address PA7 of the volatile memory 300, the information of the seventh physical address PA7 of the volatile memory 300 may be transferred to the controller 100. In case the information of the seventh physical address PA7 of the volatile memory 300 is transferred to the controller 100, the controller 100 may add the information of the seventh physical address PA7 of the volatile memory 300 to the fail information FI that is stored in the fail information region 510 included in the non-volatile memory 500 of the solid state drive 10.

In an example embodiment, the controller 100 may update the clean address list CAL and the bad address list BAL based on the updated fail information FI. For example, in case the fail information FI is updated to add the information of the seventh physical address PA7 of the volatile memory 300 to the fail information region 510, the fail addresses corresponding to the fail cells among the first to tenth physical addresses PA1 to PA10 included in the volatile memory 300 of the solid state drive 10 may be the third physical address PA3, the fifth physical address PA5, the seventh physical address PA7 and the ninth physical address PA9. The updated fail information FI may be the information about the third physical address PA3, the fifth physical address PA5, the seventh physical address PA7 and the ninth physical address PA9. In this case, the updated bad address list UBAL that is generated based on the updated fail information FI may include the third physical address PA3, the fifth physical address PA5, the seventh physical address PA7 and the ninth physical address PA9. The updated clean address list UCAL that is generated based on the updated fail information FI may include the first physical address PA1, the second physical address PA2, the fourth physical address PA4, the sixth physical address PA6, the eighth physical address PA8 and the tenth physical address PA10. The controller 100 may map the logical addresses LA of the data DATA to the physical addresses PA of the volatile memory 300 based on the updated bad address list UBAL and the updated clean address list UCAL.

In an example embodiment, the controller 100 may sequentially map the logical addresses LA of the data DATA to normal addresses corresponding to normal cells of the volatile memory 300 based on the updated clean address list UCAL. For example, the logical addresses LA of the data DATA may be the first to sixth logical addresses LA1 to LA6. The physical addresses PA of the volatile memory 300 included in the updated clean address list UCAL may be the first physical address PA1, the second physical address PA2, the fourth physical address PA4, the sixth physical address PA6, the eighth physical address PA8 and the tenth physical address PA10. The controller 100 may sequentially map the logical addresses LA of the data DATA to the normal addresses based on the updated clean address list UCAL. For example, the controller 100 may map the first logical address LA1 of the data DATA to the first physical address PA1, map the second logical address LA2 of the data DATA to the second physical address PA2, map the third logical address LA3 of the data DATA to the fourth physical address PA4, map the fourth logical address LA4 of the data DATA to the sixth physical address PA6, map the fifth logical address LA5 of the data DATA to the eighth physical address PA8 and map the sixth logical address LA6 of the data DATA to the tenth physical address PA10.

In an example embodiment, the controller 100 may stop mapping the logical addresses LA of the data DATA to fail addresses corresponding to failed cells of the volatile memory 300 based on the updated bad address list UBAL.

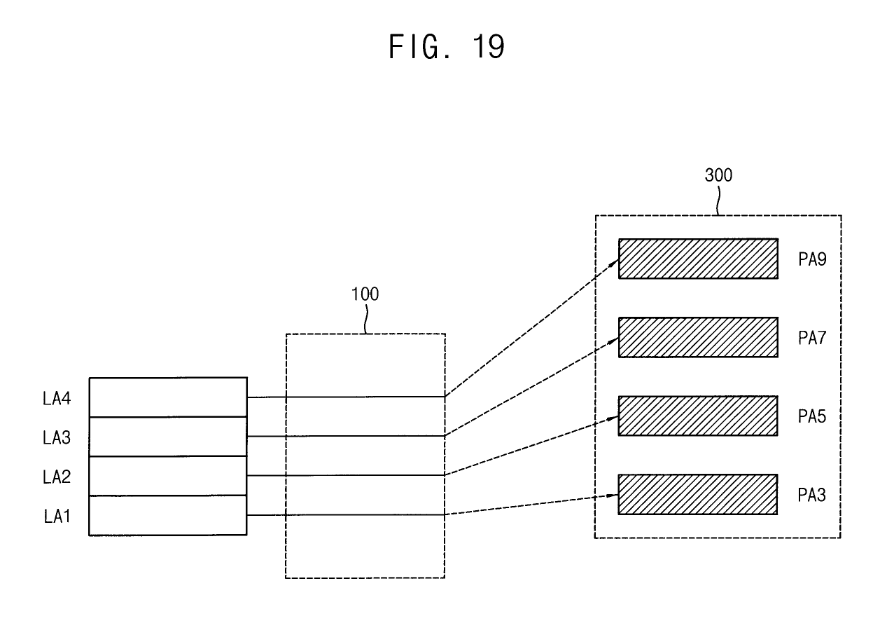

FIG. 19 is a diagram illustrating an operation example of blocking access to fail addresses based on an updated bad address list.

Referring to FIG. 19, the updated bad address list UBAL that is generated based on the updated fail information FI may include fail addresses corresponding to failed cells of the volatile memory 300. The updated bad address list UBAL may be placed in the controller 100. For example, the fail addresses corresponding to the failed cells among the first to tenth physical addresses PA1 to PA10 included in the volatile memory 300 of the solid state drive 10 may be the third physical address PA3, the fifth physical address PA5, the seventh physical address PA7 and the ninth physical address PA9. In this case, the updated bad address list UBAL that is generated based on the updated fail information FI may include the third physical address PA3, the fifth physical address PA5, the seventh physical address PA7 and the ninth physical address PA9.

In an example embodiment, the controller 100 may stop mapping the logical addresses LA of the data DATA to the fail addresses based on the updated bad address list UBAL. For example, the logical addresses LA of the data DATA may be the first to fourth logical addresses LA1 to LA4. The controller 100 may stop mapping the first logical address LA1 of the data DATA to the third physical address PA3, the fifth physical address PA5, the seventh physical address PA7 and the ninth physical address PA9. In addition, the controller 100 may stop mapping the second logical address LA2 of the data DATA to the third physical address PA3, the fifth physical address PA5, the seventh physical address PA7 and the ninth physical address PA9. In addition, the controller 100 may stop mapping the third logical address LA3 of the data DATA to the third physical address PA3, the fifth physical address PA5, the seventh physical address PA7 and the ninth physical address PA9. In addition, the controller 100 may stop mapping the fourth logical address LA4 of the data DATA to the third physical address PA3, the fifth physical address PA5, the seventh physical address PA7 and the ninth physical address PA9.

The method of operating a solid state drive may block access to fail addresses corresponding to failed cells included in the solid state drive 10 by sequentially mapping logical addresses LA to physical addresses PA of a volatile memory 300 included in the solid state drive 10 based on a clean address list CAL and a bad address list BAL that are generated based on a fail information FI.

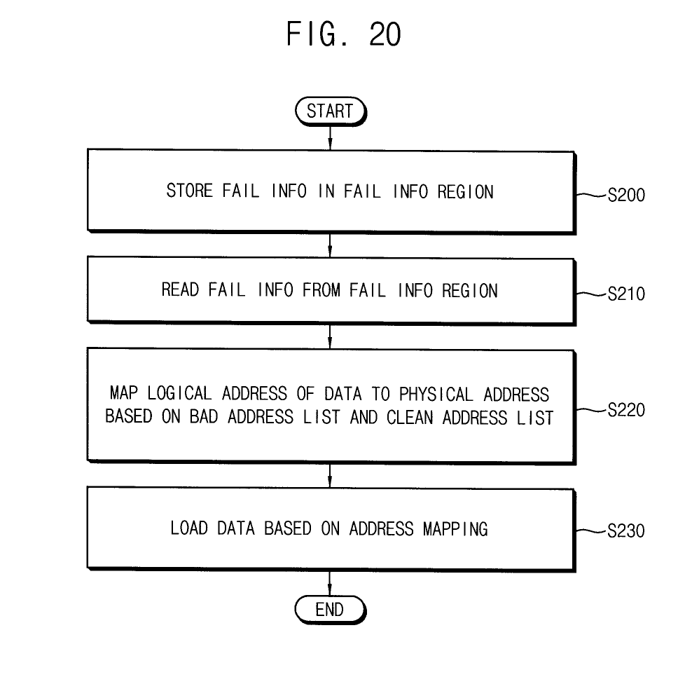

FIG. 20 is a flow chart illustrating a method of operating a solid state drive according to an example embodiment.

Referring to FIGS. 2, 3 and 20, a solid state drive 10 may include a non-volatile memory 500, a volatile memory 300 and a controller 100. If the power supply voltage is applied to the solid state drive 10, the controller 100, the non-volatile memory 500 and the volatile memory 300 included in the solid state drive 10 may be initialized based on a boot code.

In a method of operating a solid state drive including a non-volatile memory 500, a volatile memory 300 and a controller 100, the controller 100 stores the fail information FI of the volatile memory 300 in a fail information region 510 included in the non-volatile memory 500 (S200). The controller 100 reads the fail information FI from the fail information region 510 (S210). For example, the fail information FI may be information of failed cells included in the volatile memory 300 of the solid state drive 10. The fail information FI may be stored in the fail information region 510. The fail information region 510 may be included in the non-volatile memory 500 of the solid state drive 10. After the controller 100, the non-volatile memory 500 and the volatile memory 300 included in the solid state drive 10 are initialized based on the boot code, the controller 100 may read the fail information FI of the volatile memory 300 from the fail information region 510 included in the non-volatile memory 500.

The controller 100 maps a logical address LA of data DATA to a physical address of the volatile memory 300 based on a bad address list BAL and a clean address list CAL that are generated based on the fail information FI (S220). For example, the addresses included in the volatile memory 300 of the solid state drive 10 may include a first to tenth physical addresses PA1 to PA10. The fail addresses corresponding to the fail cells among the first to tenth physical addresses PA1 to PA10 included in the volatile memory 300 of the solid state drive 10 may be the third physical address PA3, the fifth physical address PA5 and the ninth physical address PA9. In this case, the fail information FI may be the information about the third physical address PA3, the fifth physical address PA5 and the ninth physical address PA9. The bad address list BAL that is generated based on the fail information FI may include the third physical address PA3, the fifth physical address PA5 and the ninth physical address PA9. The clean address list CAL that is generated based on the fail information FI may include the first physical address PA1, the second physical address PA2, the fourth physical address PA4, the sixth physical address PA6, the seventh physical address PA7, the eighth physical address PA8 and the tenth physical address PA10. The controller 100 may map the logical addresses LA of the data DATA to the physical addresses PA of the volatile memory 300 based on the bad address list BAL and the clean address list CAL.

The controller 100 loads the data DATA into the volatile memory 300 according to the address mapping (S230). The controller 100 may map the logical addresses LA of the data DATA to the physical address of the volatile memory 300 based on the clean address list CAL. For example, the controller 100 may sequentially map the logical addresses LA of the data DATA to the first physical address PA1, the second physical address PA2, the fourth physical address PA4, the sixth physical address PA6, the seventh physical address PA7, the eighth physical address PA8 and the tenth physical address PA10 corresponding to the clean address list CAL. The controller 100 may load the data DATA into the volatile memory 300. The data DATA may be included in the input signal IS. In addition, the data DATA may be provided from the non-volatile memory 500.

In addition, in an embodiment of the present disclosure, a three dimensional (3D) memory array is provided in the solid state drive 10. The 3D memory array is monolithically formed in one or more physical levels of arrays of memory cells having an active area disposed above a silicon substrate and circuitry associated with the operation of those memory cells, whether such associated circuitry is above or within such substrate. The term “monolithic” means that layers of each level of the array are directly deposited on the layers of each underlying level of the array. The following patent documents, which are hereby incorporated by reference, describe suitable configurations for the 3D memory arrays, in which the three-dimensional memory array is configured as a plurality of levels, with word-lines and/or bit-lines shared between levels: U.S. Pat. Nos. 7,679,133; 8,553,466; 8,654,587; 8,559,235; and US Pat. Pub. No. 2011/0233648.

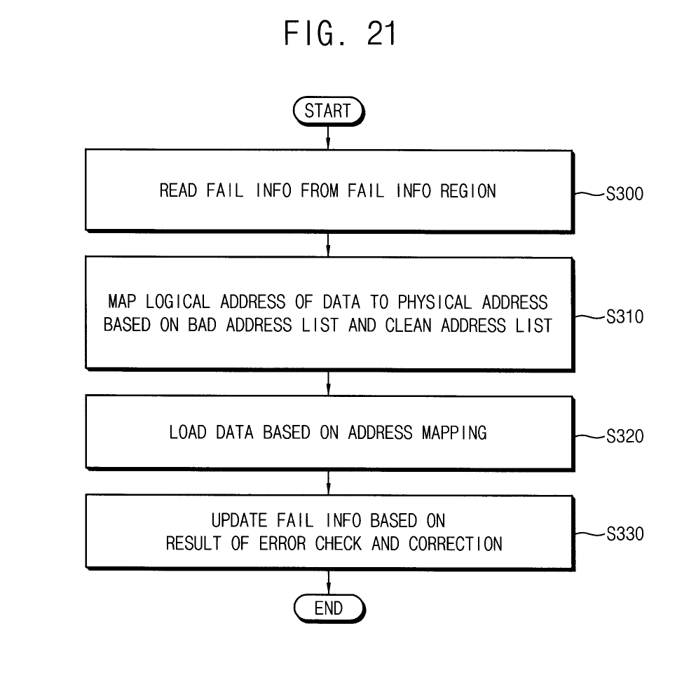

FIG. 21 is a flow chart illustrating a method of operating a solid state drive according to example embodiments.

Referring to FIG. 21, in a method of operating a solid state drive including a non-volatile memory 500, a volatile memory 300 and a controller 100, the controller 100 reads fail information FI of the volatile memory 300 from a fail information region 510 included in the non-volatile memory 500 (S300). The controller 100 maps a logical address LA of data DATA to a physical address of the volatile memory 300 based on a bad address list BAL and a clean address list CAL that are generated based on the fail information FI (S310). The controller 100 loads the data DATA into the volatile memory 300 according to the address mapping (S320). The fail information FI stored in the fail information region 510 is updated based on a result ECCR of an error check and correction that is performed while the solid state drive 10 operates (S330). For example, the controller 100 may stop mapping the logical addresses LA of the data DATA to fail addresses corresponding to fail cells of the volatile memory 300 based on the updated bad address list UBAL.

The method of operating a solid state drive may block access to fail addresses corresponding to failED cells included in the solid state drive 10 by sequentially mapping logical addresses LA to physical addresses PA of a volatile memory 300 included in the solid state drive 10 based on a clean address list CAL and a bad address list BAL that are generated based on a fail information FI.

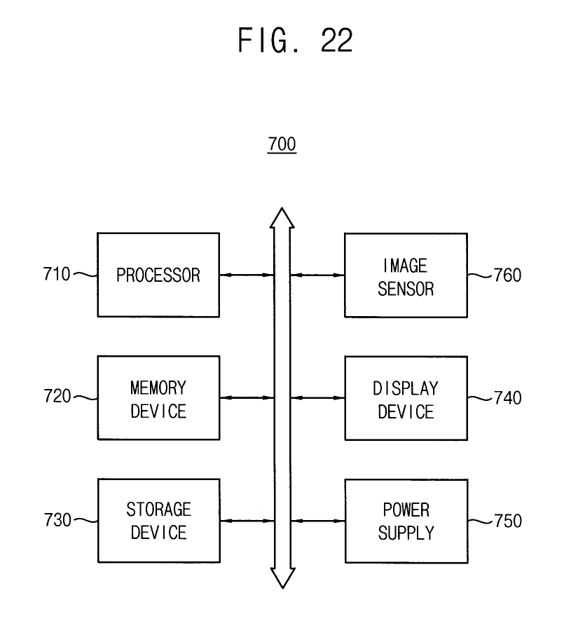

FIG. 22 is a block diagram illustrating a mobile device including the solid state drive according to example embodiments.

Referring to FIG. 22, a mobile device 700 may include a processor 710, a memory device 720, a storage device 730, a display device 740, a power supply 750 and an image sensor 760. The mobile device 700 may further include ports that communicate with a video card, a sound card, a memory card, a USB device, other electronic devices, etc.

The processor 710 may perform various calculations or tasks. According to embodiments, the processor 710 may be a microprocessor or a CPU. The processor 710 may communicate with the memory device 720, the storage device 730, and the display device 740 via an address bus, a control bus, and/or a data bus. In some embodiments, the processor 710 may be coupled to an extended bus, such as a peripheral component interconnection (PCI) bus. The memory device 720 may store data for operating the mobile device 700. For example, the memory device 720 may be implemented with a dynamic random access memory (DRAM) device, a mobile DRAM device, a static random access memory (SRAM) device, a phase-change random access memory (PRAM) device, a ferroelectric random access memory (FRAM) device, a resistive random access memory (RRAM) device, and/or a magnetic random access memory (MRAM) device. The memory device 720 includes the data loading circuit according to example embodiments. The storage device 730 may include a solid state drive (SSD), a hard disk drive (HDD), a CD-ROM, etc. The mobile device 700 may further include an input device such as a touchscreen, a keyboard, a keypad, a mouse, etc., and an output device such as a printer, a display device, etc. The power supply 750 supplies operation voltages for the mobile device 700.

The image sensor 760 may communicate with the processor 710 via the buses or other communication links. The image sensor 760 may be integrated with the processor 710 in one chip, or the image sensor 760 and the processor 710 may be implemented as separate chips.

At least a portion of the mobile device 700 may be packaged in various forms, such as package on package (PoP), ball grid arrays (BGAs), chip scale packages (CSPs), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flat pack (TQFP), small outline IC (SOIC), shrink small outline package (SSOP), thin small outline package (TSOP), system in package (SIP), multi chip package (MCP), wafer-level fabricated package (WFP), or wafer-level processed stack package (WSP). The mobile device 700 may be a digital camera, a mobile phone, a smart phone, a portable multimedia player (PMP), a personal digital assistant (PDA), a computer, etc.

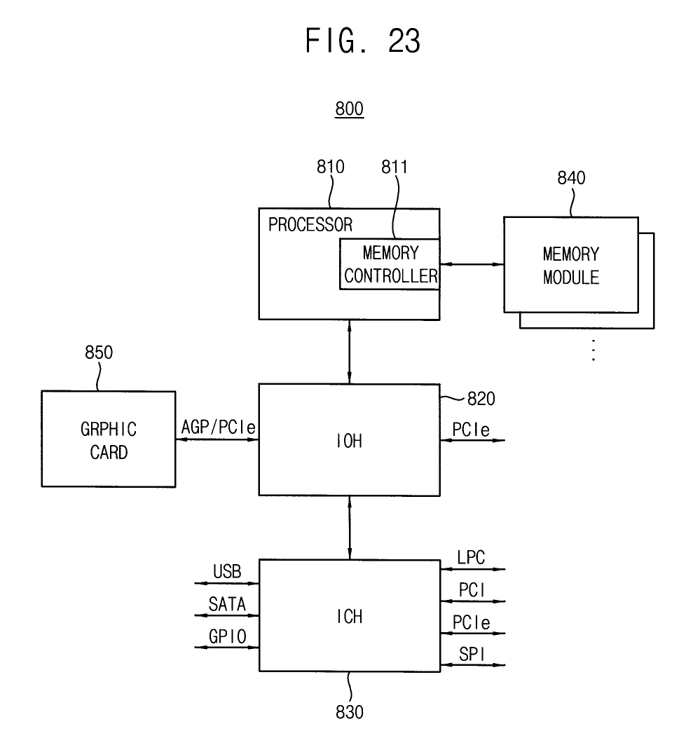

FIG. 23 is a block diagram illustrating a computing system including the solid state drive according to example embodiments.

Referring to FIG. 23, a computing system 800 includes a processor 810, an input/output hub (IOH) 820, an input/output controller hub (ICH) 830, at least one memory module 840 and a graphics card 850. In some embodiments, the computing system 800 may be a personal computer (PC), a server computer, a workstation, a laptop computer, a mobile phone, a smart phone, a personal digital assistant (PDA), a portable multimedia player (PMP), a digital camera), a digital television, a set-top box, a music player, a portable game console, a navigation system, etc.

The processor 810 may perform various computing functions, such as executing specific software for performing specific calculations or tasks. For example, the processor 810 may be a microprocessor, a central process unit (CPU), a digital signal processor, or the like. In some embodiments, the processor 810 may include a single core or multiple cores. For example, the processor 810 may be a multi-core processor, such as a dual-core processor, a quad-core processor, a hexa-core processor, etc. In some embodiments, the computing system 800 may include a plurality of processors. The processor 810 may include an internal or external cache memory.

The processor 810 may include a memory controller 811 for controlling operations of the memory module 840. The memory controller 811 included in the processor 810 may be referred to as an integrated memory controller (IMC). A memory interface between the memory controller 811 and the memory module 840 may be implemented with a single channel including a plurality of signal lines, or may be implemented with multiple channels, to each of which at least one memory module 840 may be coupled. In some embodiments, the memory controller 811 may be located inside the input/output hub 820, which may be referred to as memory controller hub (MCH).

The input/output hub 820 may manage data transfer between processor 810 and devices, such as the graphics card 850. The input/output hub 820 may be coupled to the processor 810 via various interfaces. For example, the interface between the processor 810 and the input/output hub 820 may be a front side bus (FSB), a system bus, a HyperTransport, a lightning data transport (LDT), a QuickPath interconnect (QPI), a common system interface (CSI), etc. In some embodiments, the computing system 800 may include a plurality of input/output hubs. The input/output hub 820 may provide various interfaces with the devices. For example, the input/output hub 820 may provide an accelerated graphics port (AGP) interface, a peripheral component interface-express (PCIe), a communications streaming architecture (CSA) interface, etc.

The graphics card 850 may be coupled to the input/output hub 820 via AGP or PCIe. The graphics card 850 may control a display device (not shown) for displaying an image. The graphics card 850 may include an internal processor for processing image data and an internal memory device. In some embodiments, the input/output hub 820 may include an internal graphics device along with or instead of the graphics card 850 outside the graphics card 850. The graphics device included in the input/output hub 820 may be referred to as integrated graphics. Further, the input/output hub 820 including the internal memory controller and the internal graphics device may be referred to as a graphics and memory controller hub (GMCH).

The input/output controller hub 830 may perform data buffering and interface arbitration to efficiently operate various system interfaces. The input/output controller hub 830 may be coupled to the input/output hub 820 via an internal bus, such as a direct media interface (DMI), a hub interface, an enterprise Southbridge interface (ESI), PCIe, etc. The input/output controller hub 830 may provide various interfaces with peripheral devices. For example, the input/output controller hub 830 may provide a universal serial bus (USB) port, a serial advanced technology attachment (SATA) port, a general purpose input/output (GPIO), a low pin count (LPC) bus, a serial peripheral interface (SPI), PCI, PCIe, etc.

In some embodiments, the processor 810, the input/output hub 820 and the input/output controller hub 830 may be implemented as separate chipsets or separate integrated circuits. In other embodiments, at least two of the processor 810, the input/output hub 820 and the input/output controller hub 830 may be implemented as a single chipset.

The present inventive concept may be applied to systems such as be a mobile phone, a smart phone, a personal digital assistant (PDA), a portable multimedia player (PMP), a digital camera, a music player, a portable game console, a navigation system, etc. The foregoing is illustrative of exemplary embodiments and is not to be construed as limiting thereof. Although a few exemplary embodiments have been described, those skilled in the art will readily appreciate that many modifications are possible in the exemplary embodiments without materially departing from the novel teachings and advantages of the present inventive concept. Accordingly, all such modifications are intended to be included within the scope of the present inventive concept as defined in the claims.

What is claimed is:

1. A method of operating a solid state drive including a non-volatile memory, a volatile memory and a controller, the method comprising:
reading, by the controller, fail information of the volatile memory from a fail information region included in the non-volatile memory;
mapping, by the controller, a logical address of data to a physical address of the volatile memory based on a bad address list and a clean address list that are generated based on the fail information; and
loading, by the controller, the data into the volatile memory according to the address mapping.

2. The method of claim 1, wherein the clean address list that is generated based on the fail information includes normal addresses corresponding to normal cells of the volatile memory.

3. The method of claim 2, wherein the clean address list includes a mapping table that sequentially maps the logical addresses of the data to the normal addresses.

4. The method of claim 3, wherein the controller sequentially maps the logical addresses of the data to the normal addresses based on the clean address list.

5. The method of claim 2, wherein the clean address list is stored in the volatile memory.

6. The method of claim 5, wherein the controller includes a plurality of central processor units, each of the central processor units sequentially maps the logical addresses of the data to the normal addresses based on the clean address list.

7. The method of claim 1, wherein the bad address list that is generated based on the fail information includes fail addresses corresponding to failed cells of the volatile memory.

8. The method of claim 7, wherein the controller does not map the logical addresses of the data to the fail addresses based on the bad address list.

9. The method of claim 1, wherein the fail information is stored in the fail information region based on a test result of the volatile memory; and wherein the test result is determined by a test that is performed before the volatile memory is packaged.

10. The method of claim 1, wherein the fail information stored in the fail information region is updated based on a result of an error check and correction that is performed during operation of the solid state drive.

11. The method of claim 10, wherein the controller updates the clean address list and the bad address list based on updated fail information.

12. The method of claim 11, wherein the controller sequentially maps the logical addresses of the data to normal addresses corresponding to normal cells of the volatile memory based on the updated clean address list.

13. The method of claim 11, wherein the controller does not map the logical addresses of the data to fail addresses corresponding to failed cells of the volatile memory based on the updated bad address list.

14. A method of operating a solid state drive including a non-volatile memory, a volatile memory and a controller, the method comprising:
storing, by the controller, fail information of the volatile memory in a fail information region included in the non-volatile memory;
reading, by the controller, the fail information from the fail information region;
mapping, by the controller, a logical address of data to a physical address of the volatile memory based on a bad address list and a clean address list that are generated based on the fail information; and
loading, by the controller, the data into the volatile memory according to the address mapping.

15. The method of claim 14, wherein the controller sequentially maps the logical addresses of the data to normal addresses corresponding to normal cells of the volatile memory based on the clean address list.

16. The method of claim 14, wherein the non-volatile memory and the volatile memory included in the solid state drive include a three-dimensional memory array.

17. A solid state drive comprising:
a non-volatile memory;
a volatile memory; and
a controller configured to read fail information of the volatile memory from a fail information region included in the non-volatile memory, map a logical address of data to a physical address of the volatile memory based on a bad address list and a clean address list that are generated based on the fail information, and load the data into the volatile memory according to the address mapping.

18. The solid state drive of claim 17, wherein the clean address list that is generated based on the fail information includes normal addresses corresponding to normal cells of the volatile memory, and the bad address list that is generated based on the fail information includes fail addresses corresponding to failed cells of the volatile memory.

19. The solid state drive of claim 18, wherein the volatile memory is configured to store the clean address list which includes a mapping table that maps the logical addresses of the data to the normal addresses; and wherein the controller maps the logical addresses of the data to the normal addresses based on the clean address list.

20. The solid state drive of claim 19, wherein the controller includes a plurality of central processor units configured to map the logical addresses of the data to the normal addresses based on the clean address list.
